(19) United States
(12) Patent Application Publication
(10) Pub. No.: US 2024/0385216 A1
(43) Pub. Date: Nov. 21, 2024

(54) Electrical and Optical Semiconductor Probe Head

(71) Applicant: Teramount Ltd., Jerusalem (IL)

(72) Inventors: Hesham Taha, Jerusalem (IL); Abraham Israel, Jerusalem (IL)

(21) Appl. No.: 18/663,193

(22) Filed: May 14, 2024

Related U.S. Application Data
(60) Provisional application No. 63/502,180, filed on May 15, 2023.

(51) Int. Cl. G01R 1/067; G01R 31/311

(52) U.S. Cl. CPC G01R 1/06722; G01R 31/311

(57) ABSTRACT

Systems, apparatuses, and methods are described for semiconductor substrate probing and testing. Specifically, systems, apparatuses, and methods are described for electrically probing and optically probing a substrate in parallel. The parallel probing is enabled by a surface coupling optical arrangement utilizing a photonic bump.

### CROSS-REFERENCE TO RELATED APPLICATIONS

The present application claims the benefit of and priority to U.S. Provisional Application No. 63/502,180, filed May 15, 2023. The contents of the aforementioned application are incorporated herein by reference in their entirety.

### BACKGROUND

Semiconductors may be configured for electrical and/or photonic applications. Inspection is used as a part of semiconductor manufacturing and testing. Testing or probing is critical to maintaining fabrication and packaging yield.

### SUMMARY

The following summary presents a simplified summary of certain features. The summary is not an extensive overview and is not intended to identify key or critical elements.

Systems, apparatuses and methods are described for probing and/or testing optical circuitry and electrical circuitry, for example, in substrates (e.g., semiconductor substrates). Substrates (e.g., wafers) may include optical and electrical circuitry on the same substrate. Systems, apparatuses and methods are described for parallel probing of the optical and electrical circuits. Probe assemblies are described comprising optical, electrical, and optical/electrical probe heads. In this way, testing efficiency and manufacturing yield of substrates may be improved.

These and other features and advantages are described in greater detail herein.

### BRIEF DESCRIPTION OF THE DRAWINGS

Some features are shown by way of example, and not by limitation, in the accompanying drawings. In the drawings, like numerals reference similar elements.

FIG. 1 depicts an example probe assembly according to one or more aspects of the present disclosure.

FIG. 2 depicts an example probe assembly in the context of probing an example test substrate.

FIG. 3 depicts an example isolated optical probe mounting assembly according to one or more aspects of the present disclosure.

FIG. 4 depicts an alternative example of an optical probe mounting assembly according to one or more aspects of the present disclosure.

FIG. 5 depicts an alternative example probe assembly.

FIG. 6 depicts an example test substrate.

FIG. 7 depicts an example test substrate.

FIG. 8 depicts an example probe assembly.

FIG. 9 depicts hardware elements of a computing device that may be used to implement and any other computing devices discussed herein.

### DETAILED DESCRIPTION

The accompanying drawings, which form a part hereof, show examples of the disclosure. It is to be understood that the examples shown in the drawings and/or discussed herein are non-exclusive and that there are other examples of how the disclosure may be practiced.

Probe stations (e.g., assemblies) may be used for substrate (e.g., semiconductor) testing at various fabrication and/or packaging points. For example, probe stations may be used for wafer-level testing, die-level testing, chiplet-level testing, board-level testing, etc. Probe stations may provide, for example, electrodes on motorized stages, which may be supported by appropriate software to manage the multiple testing points. For electrical testing, a voltage or current may be provided through the electrodes to the die circuits. Feedback from different tested points may be measured.

Semiconductor substrates may be configured to include photonic or both electrical and photonic circuitry. Such substrates may comprise, for example, silicon-photonic (SiPh) substrates. For such SiPh substrates, there remains a need to test, in parallel, the electrical and optical functionalities. Additionally, for SiPh substrates, there remains a need to conveniently test the optical functionalities. Accordingly, aspects of probe heads that address some of the described shortcomings and more are described herein.

Particularly, described herein are probe heads that may address both electrical and optical substrate testing. Additionally, described herein are optical probe heads that enable optical and electrical testing in parallel. The optical probe head may be based on an integration of a photonic plug with an electrical probe head. Some example photonic plugs are described in detail in commonly assigned U.S. patent application Ser. No. 17/989,303 (the “'303 application”) titled OPTICAL COUPLING, the contents of which are incorporated herein by reference in their entirety.

The above-incorporated '303 application describes a photonic bump in detail. The photonic bump, amongst other advantages, enables optical surface coupling to a SiPh die, for example, a photonic integrated circuit (PIC). As described, the photonic bump may enable “self-alignment optics” and may transfer the precision requirements from the assembly domain to the fabrication domain by utilizing the more easily achieved precision of silicon fabrication processes, for example, wafer-level manufacturing processes, to accurately place an optical element (e.g., a curved mirror) at an accurate predefined distance from an optical transceiver component (e.g., input/output). The photonic bump enables optical surface coupling and eases the tolerances, in the X, Y, and Z directions, of connector or plug assembly (e.g., self-aligning optics).

Substrate testing may be used for improving fabrication and packaging processes, for example, by sorting good dies from bad dies at the wafer stage. In addition to the advantages mentioned above, the photonic bump may be leveraged to streamline optical substrate testing. For example, the photonic bump may enable flexible extraction of the light beam from the surface of the substrate and enables beam expansion. This may facilitate the self-aligning optics scheme for increased tolerances in the X, Y, and Z directions.

Additionally, the photonic bump may allow for the combination of electrical and optical probing in parallel. The parallel probing is enabled at least for the following reasons. First, the planar geometry afforded by the photonic bump enables parallel optical and electrical probing. Second, the surface coupling capabilities (including for non-grating coupler based SiPh substrates) enable a vertical probe point (similar to electrical probing). The vertical probe point additionally advantageously enables substrate testing prior to dicing (which vastly streamlines the testing process). Typical optical side coupling substrates may not have the ability for inspection prior to wafer dicing (unless extra elements are used, e.g., gratings). Third, the large assembly tolerances afforded by the photonic bump and photonic plug facilitate locating the inspection points and cases placement tolerances

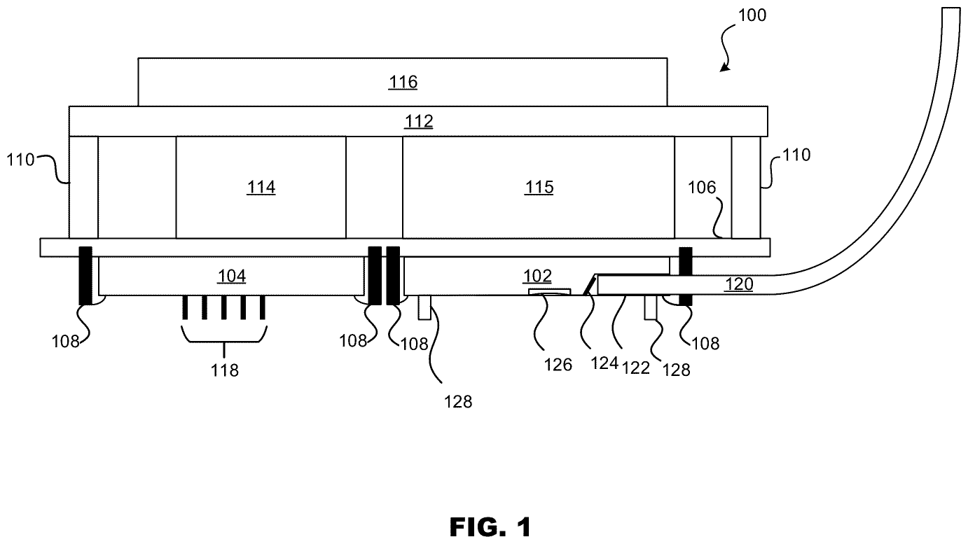

FIG. 1 depicts an example probe assembly 100 according to one or more aspects of the present disclosure. Referring to FIG. 1, the probe assembly 100 may comprise an optical probe head 102 and an electrical probe head 104. The optical probe head 102 and electrical probe heads may be connected to a probe head holder 106. Accordingly, the optical probe plane and the electrical probe plane may be substantially parallel to each other. In other example configurations, the optical probe plane and the electrical probe plane may be offset by an angle, for example, from about 0° to at least about 60°. Such a configuration may allow for simplified optical and electrical substrate testing in parallel, as described herein.

The probe head holder 106 may comprise one or more probe head clamps 108. The optical probe head 102 and the electrical probe head 104 may be secured to the probe head holder 106 via the probe head clamps 108. The probe head clamps 108 may apply a force to a surface of the probe heads 102 and 104, securing the probe heads 102 and 104 in place. The probe head clamps 108 may be adjustable in height and movable (e.g., in the X and Y directions) on the probe head holder 106. Accordingly, the relative positions of the optical probe head 102 and the electrical probe head 104 may be adjusted for different substrate configurations and for fine alignment of the probe surfaces (e.g., surfaces and/or elements to be probed). Although the optical probe head 102 and electrical probe head 104 are depicted as substantially parallel, in other example configurations, the probe head planes may be offset. For example, the probe head clamps 108 may be used to retain the optical probe head 102 at an angle (e.g., 30°) to the electrical probe head 104.

The probe assembly 100 may further comprise one or more additional intermediate structures for securing the probe heads 102 and 104 to a probe station and for assisting in various testing functions. For example, the probe assembly 100 may further comprise one or more probe head holder mounts 110. The probe head holder mounts 110 may be, for example, mechanically configured to secure the probe head holder 106 to the remainder of the probe assembly 100. The probe head holder mounts 110 may be adjustable to allow for various testing configurations. Additionally, the probe head holder mounts 110 may allow for the integration of other testing components.

The probe assembly 100 may further comprise a printed circuit board (PCB) 112. The PCB 112 may comprise electrical circuitry. The electrical circuitry may be configured for connecting the electrical probe head 104 to measuring tools (e.g., oscilloscope, multimeter, LCR meter (inductance capacitance resistance meter), semiconductor analyzer, network analyzer, spectrum analyzer, etc.) and/or power. Additionally or alternatively, the electrical circuitry of the PCB 112 may be configured for connecting the optical probe head 102 to measuring tools and/or power. The PCB 112 may further comprise various circuits (e.g., application-specific integrated circuits (ASICs)) and/or components for achieving the testing functionality.

The probe assembly 100 may further comprise one or more interposers 114. The interposer 114 may comprise active and or passive electrical components and/or circuitry (e.g., electrical pads, electrical bumps, electrical traces, ASICs, etc.) to facilitate the electrical connection of the electrical probe head 104 to the measuring tools, for example, via the PCB 112.

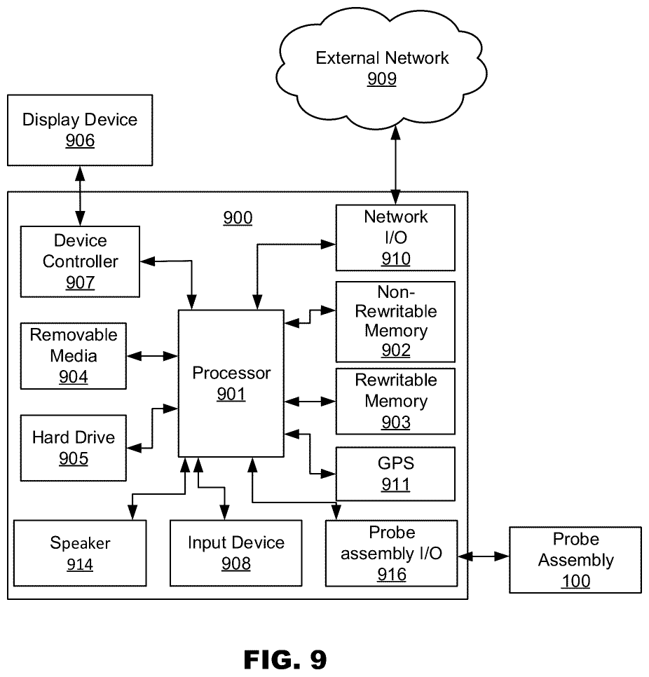

The probe assembly 100 may further comprise probe station interface 116. The probe station interface 116 may be mechanically configured to connect to the probe station. Additionally, the probe station interface may include optical and or electrical components to facilitate movement of the probe assembly 100 and to facilitate optical and/or electrical testing and integration with a probe station. The probe station interface may additionally or alternatively interface with a computing device (e.g., computing device 900 of FIG. 9) to control and/or monitor the various aspects and elements of the probe assembly 100.

The probe assembly 100 may further comprise an optical probe mounting assembly 115. The optical probe mounting assembly 115 will be described below in more detail. The optical probe mounting assembly may be connected to one or more of any of the PCB 112, the probe head holder 106, the probe station interface 116, or any other components. The optical probe head 102 may be movably mounted to the optical probe mounting assembly 115, as will be described below in greater detail. The optical probe mounting assembly 115 may operate similarly to and/or in conjunction with the probe head holder mounts 110. Additionally, the optical probe head 102 may be used in conjunction with electrical functionality (e.g., to facilitate testing). According to such configurations, the optical probe mounting assembly may additionally include features similar to the interposer 114 to assist electrical connection (e.g., of the optical and/or electrical probe heads 102 and 104). Although the components of probe assembly 100 are described and depicted in the figures as being arranged in a particular order, the arrangement and order of components should not be understood as limiting.

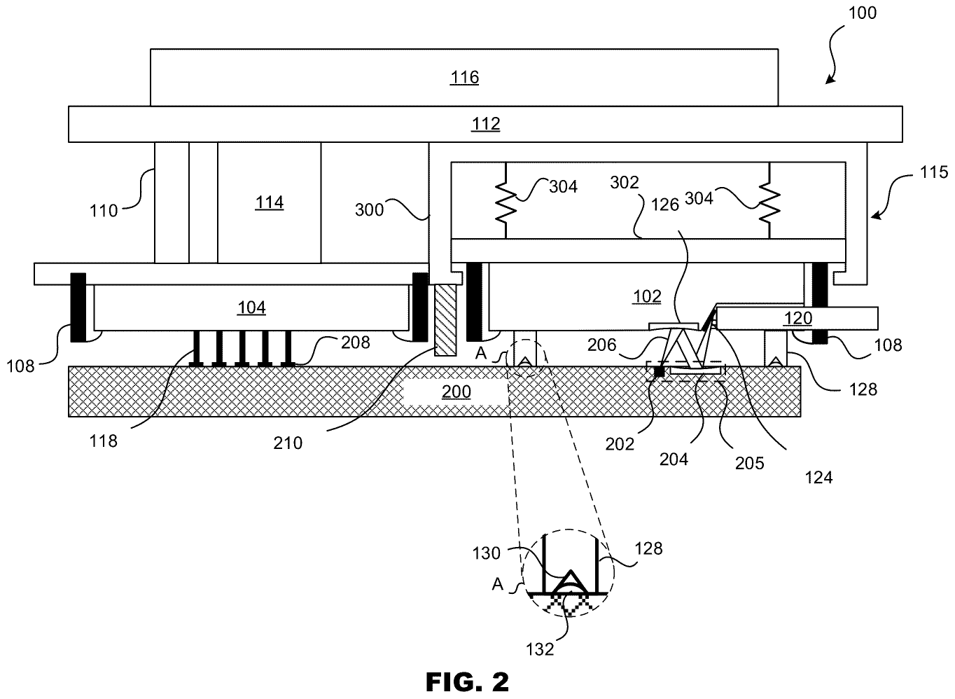

The electrical probe head 104 (e.g., at the probe-side testing surface) may comprise electrical probing pins 118. The electrical probing pins 118 may be connected to the PCB 112 (e.g., via the interposer 114). The electrical probing pins 118 may contact the electrical probe points of the electrical circuit to be tested (Sec, e.g., FIG. 2). Voltage and/or current may be applied to the electrical circuits to be tested via the electrical probing pins 118. Additionally, the electrical probing pins 118 may be electrically connected to one or more measuring tools (e.g., oscilloscope, multimeter, LCR meter, semiconductor analyzer, network analyzer, spectrum analyzer, etc.), for example, via the interposer 114 and/or the PCB 112.

The optical probe head 102 may be substantially similar in configuration to the photonic plug described in the herein incorporated '303 application. An optical fiber 120 (e.g., single-mode fiber, multi-mode fiber, few-mode fiber, etc.) may be connected to the optical probe head 102. To accommodate the optical fiber 120, the optical probe head 102 may comprise a fiber trench 122. The fiber trench 122 may comprise, for example, a V-groove, U-groove, or hole (e.g., as described in the '303 application) to receive the optical fiber 120. The optical fiber 120 may be connected (e.g., at a second side) to optical testing/measuring tools. The optical fiber 120 may be secured to the optical probe head 102 in one or more of various ways (e.g., using epoxy, adhesives, clamping, etc.). The optical fiber 120 may be connected, at a first end, to the optical probe head 102 and, at a second end, to testing equipment (e.g., computing device 900 of FIG. 9). The optical fiber may be routed away from the probe assembly 100, for example, enabling improved mobility of the probe assembly 100.

The optical probe head 102 may further comprise a beam-turning element 124 (e.g., substantially flat mirror). The beam-turning element 124 may facilitate the optical connection of the optical fiber 120 to the substrate to be tested (as described below in additional detail). The beam-turning element 124 may be fabricated and/or placed at a predefined distance from the terminus of the installed optical fiber 120. In some example configurations, the predefined distance may comprise substantially abutting the terminus of the optical fiber 120. In alternative configurations, the beam-turning element 124 may be variously distanced from the terminus of the optical fiber 120. Different optical circuit and substrate configurations may benefit from various testing configurations. The beam-turning element 124 may be further configured to transform a light beam. For example, the beam-turning element 124 may further comprise a lensed mirror, tilted curved mirror, etc. Additionally or alternatively, the beam-turning element 124 may be configured to substantially collimate light beams and/or substantially focus light beams. Additionally or alternatively, the beam-turning element may be configured to transform a mode diameter of light beams, for example, if the test substrate uses a differently sized mode diameter from the optical fiber 120.

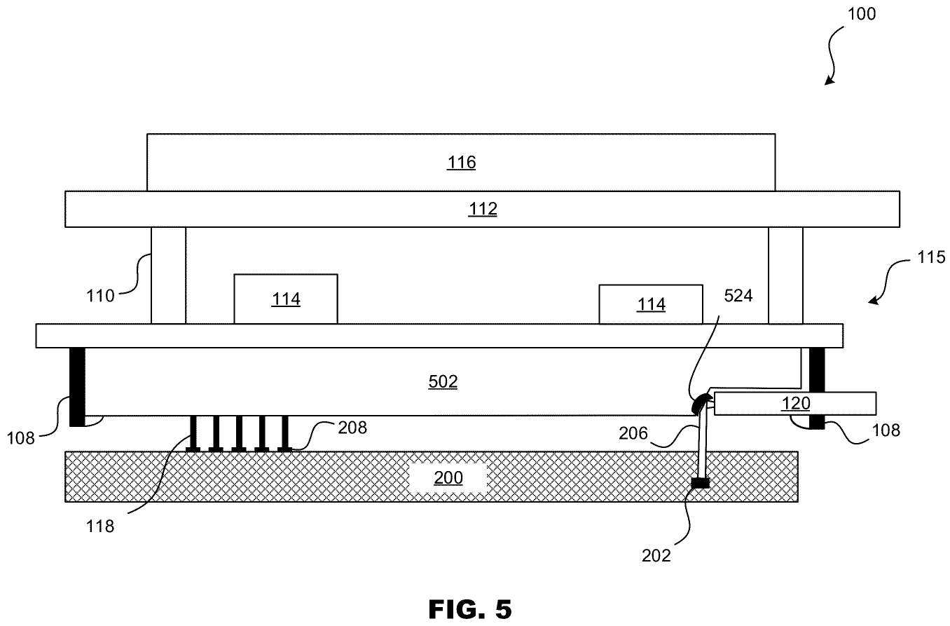

The optical probe head 102 may further comprise a probe head optical focusing element 126 (e.g., curved mirror, focusing lens, lensed mirror, etc.). The probe head optical focusing element 126 may facilitate the optical connection of the optical fiber 120 to the substrate to be tested (as described below in additional detail). Additionally, the probe head optical focusing element 126 may enable self-aligning optical schemes. The probe head optical focusing element 126 may be fabricated at a precise and/or predefined distance from the beam-turning element 124 and/or the place for the terminus of the installed optical fiber 120. Additional details of the optical probe head 102 are described below. Although the figures only depict a cross-section of a single probe head optical focusing element 126 and optical fiber 120, it should be understood that a single optical probe head 102 may comprise any number of a plurality of probe head optical focusing elements 126 and associated optical fibers 120 in parallel. For example, a single optical probe head 102 may test a plurality of optical transceivers 202 in parallel. Additionally or alternatively, for some example configurations, the probe head optical focusing element 126 may be omitted from the optical probe head 102 or may not be used for testing, for example, as depicted and described herein with reference to FIG. 5.

The optical focusing element 204 and/or the beam-turning element 124 may be fabricated in or on the optical probe head 102, for example, via wafer level manufacturing (e.g., CMOS, lithography, grayscale lithography (e.g., grayscale, imprint, etc.), etching, deposition, etc.). Additionally or alternatively, the optical focusing element 204 and/or the beam-turning element may be fabricated in or on a separate carrier (e.g., bump-on-carrier) (e.g., die, wafer, carrier substrate). The carrier (e.g., including the optical focusing element 204 and/or the beam-turning element) may be added to the optical probe head 102.

The optical probe head 102 may further comprise spacer stools 128. The spacer stools 128 may be configured to space a test substrate 200 (e.g., test substrate optical components) from the optical probe head 102. The spacer stools 128 may be height adjustable. The spacer stools 128 may comprise features for macro and/or micro height adjustments. Accordingly, the spacer stools 128 may be adjusted for testing of different optical substrate configurations (e.g., that use different optical designs). Further, the spacer stools 128 may be adjusted for precise operation of the optical testing. The spacer stools 128 may enable (e.g., cause) an air gap between the optical elements of the optical probe head 102 and the optical elements of the test substrate 200.

Spacer stools 128 may be further configured to facilitate alignment (e.g., fine alignment) between the optical elements (e.g., probe head optical focusing element 126, beam turning element 124, etc.) of the probe head (e.g., optical probe head 102) and the tested substrate 200. For example, referring to FIG. 2 (e.g., magnified callout A of FIG. 2), the spacer stools 128 may comprise a first fine alignment feature, for example, trench 130. In one example configuration, the trench 130 may comprise a v-groove. Additionally or alternatively, the trench may be otherwise configured, for example, the trench may comprise a u-groove, a pyramidal groove, etc. The test substrate may comprise a second fine alignment feature, for example, semi-sphere 132. The trenches 130 and semi-spheres may be configured to engage one another. For example, if the optical probe head 102 is drawn toward test substrate, the trenches 130 may engage the semi-spheres 132. Engagement of the trenches 130 and semi-spheres 132 may cause fine alignment of the probe head features with the test substrate features. The fine alignment may facilitate the optical connection of the optical probe head 102 to the test substrate 200 (e.g., one or more optical circuits of the test substrate 200). In this manner, the fine alignment features of the optical probe head and the test substrate 200 may provide fine in alignment in the X direction, the Y direction, height, tilt, and/or rotation. The optical probe head 102 and the test substrate may comprise any number spacer stools 128, trenches 130, and semi-spheres 132. FIG. 2 depicts an example probe assembly 100 in the context of probing an example test substrate 200. Referring to FIG. 2, it can be appreciated that the present optical scheme allows for parallel optical and electrical testing of a substrate. The test substrate 200 may comprise one or more optical transceiver 202 (e.g., one or more optical input/output components). The optical transceiver 202 may comprise one or more of, for example, a waveguide, a laser, a grating coupler, a second beam-turning element, a turning curved mirror (TCM), a multiplexer/demultiplexer, photonic bump, etc. The optical transceiver 202 may comprise the optical input and/or output of the test substrate 200. The optical transceiver 202 may be configured to couple to a collimated and/or focusing light beam.

The test substrate 200 may further comprise a substrate optical focusing element 204 (e.g., curved mirror, focusing lens, etc.). The substrate optical focusing element 204 may be fabricated and/or disposed (e.g., via wafer-level fabrication processes) at an accurate distance from the optical transceiver 202. The substrate optical focusing element 204 may facilitate the optical connection of the optical fiber 120 to the test substrate 200. The substrate optical focusing element 204, placed at an accurate distance from the optical transceiver 202, may be referred to as a photonic bump 205. The photonic bump 205 may facilitate the enablement of the optical surface coupling and the self-aligning optics referred to herein.

Accordingly, considering propagation in the direction from the test substrate 200 to the optical fiber 120, the optical beam 206 may expand as it propagates from the optical transceiver 202. The optical transceiver 202 may direct the expanding optical beam 206 in the direction of the probe head optical focusing element 126. The probe head optical focusing element 126 may receive the optical beam 206 (e.g., the optical beam 206 may be incident thereupon) and substantially collimate the optical beam 206. The probe head optical focusing element 204 may direct the collimated optical beam 206 (e.g., the collimated version of the optical beam 206) toward the substrate optical focusing element 204. The substrate optical focusing element 204 may receive (e.g., the optical beam 206 may be incident thereupon) the optical beam 206 and substantially focus the optical beam toward the optical fiber 120. The substrate optical focusing element 204 may direct the focusing optical beam 206 toward the beam-turning element 124. The beam-turning element 124 may receive the optical beam 206. The beam-turning element 124 may direct (e.g., turn) the optical beam 206 toward the optical fiber 120. While propagation of the optical beam 206 has been described as propagating from the test substrate 200, it should be understood that the optical beam 206 may similarly propagate from the optical fiber 120 (to the test substrate) in a substantially reverse process.

As can be appreciated, the present configuration of the optical elements of the test substrate 200 and the optical probe head 102 enable optical surface probing and surface testing of the test substrate 200. Thereby, the parallel surface testing of the electrical and optical components/circuitry is enabled. Additionally, a configuration of the present disclosure of the optical elements of the test substrate 200 and the optical probe head 102 may further enable self-alignment of the substrate-side optical elements with the probe-side optical elements. For example, the present configurations of the optical elements may correct some assembly misalignment and/or misalignment between optical probe head 102 and test substrate 200 in the X, Y, and/or Z directions (e.g., as described in further detail in the '303 application).

As can be appreciated with reference to FIG. 2, the probe assembly 100 may be adjustable to enable testing of different substrate configurations. For example, the probe heads 102 and 104 may be moved depending on the relationship (e.g., distance) of the electrical surfaces and optical surfaces (e.g., via moving of the probe head clamps). Additionally, different optical probe heads 102 and/or electrical probe heads 104 may be interchanged depending on the configuration of the test substrate 200. Further, the spacer stools 128 may be adjusted (as described above) to distance (e.g., space) the probe-side optical elements and the substrate-side optical elements as desired.

In addition to optical connection to enable optical probing and/or testing of the test substrate 200, the probe assembly 100 may enable electrical probing and/or testing of the test substrate 200. For example, the electrical probing pins 118 may be brought towards and electrically connect to (e.g., contact) substrate electrical contacts 208 to apply and receive electrical signals, voltage, and/or current to and/or from the test substrate 200.

The mechanics of the probe assembly 100 may enable both optical and electrical functionalities while probing the substrate 200. Accordingly, if the electrical probing pins 118 are in contact with the substrate electrical contacts 208 at an appropriate force, the optical probe head 102 may be maintained at an appropriate height and tilt for establishing the desired conditions for the optical testing. Accordingly, the optical probe mounting assembly 115 may include height and tilt adjustment mechanisms, as described in more detail herein.

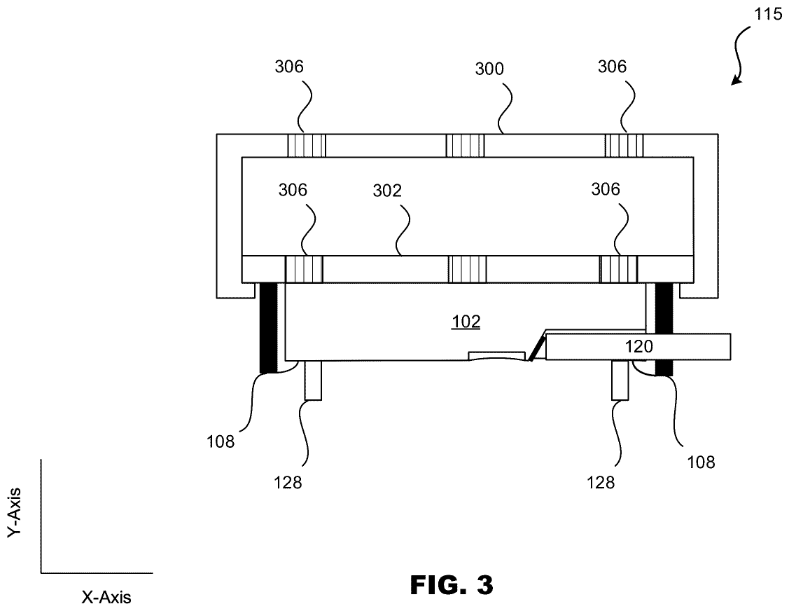

FIG. 3 depicts an example isolated optical probe mounting assembly 115. Referring to FIG. 3, the optical probe mounting assembly 115 may comprise a mounting support structure 300. According to some configurations, the mounting support structure may comprise a housing. The mounting support structure 300 may be connected to one or more of different components of the probe assembly 100 (e.g., probe assembly 100 of FIG. 1, FIG. 2, or FIG. 5). For example, the mounting support structure 300 may be connected to one or more of the probe head holders 106 (depicted, e.g., in FIG. 1 and FIG. 2), the PCB 112 (depicted, e.g., in FIG. 2, FIG. 5), and/or the probe station interface 116 (depicted, e.g., in FIG. 1, FIG. 2, FIG. 5). The optical probe mounting assembly 115 may additionally comprise an optical probe head mounting platform 302. According to some configurations, the optical probe head mounting platform 302 may be substantially similar to the probe head holder 106, as described herein. The optical probe head mounting platform 302 may be movably (e.g., slidably) attached to the mounting support structure 300. The optical probe head mounting platform 302 and/or the mounting support structure 300 may comprise one or more rails, guides, tracks, carriages, bearings, etc., for example, to facilitate relative movement between the mounting support structure and the optical probe head mounting platform 302. The optical probe head mounting platform 302 may comprise one or more probe head clamps 108. The probe head clamps may be adjustable in height and may be moveable (e.g., in the X and Y directions) on the probe head mounting platform 302, for example, to accommodate different optical probe heads 102. Optical probe heads 102 may be secured to the optical probe head mounting platform 302, for example, via the one or more probe head clamps 108.

As described with reference to FIG. 2, the optical probe head mounting assembly 115 may comprise restorative force features (e.g., springs 304, magnets, hydraulics, etc.). For example, referring to FIG. 2, the optical probe mounting assembly 115 may comprise one or more springs 304. The springs 304 may be connected between and/or to the mounting support structure 300 and the optical probe head mounting platform 302. The springs 304 may apply a restorative force to the optical probe head mounting platform, for example, a force in the direction of the test substrate (e.g., test substrate 200 as depicted in FIG. 2). Accordingly, the movable nature of the optical probe head mounting platform 302, and the restorative force of the springs 304, may allow for desired engagement of the optical probe head 102 and the test substrate 200.

With continued reference to FIG. 2, it may be appreciated how an example configuration of the probe assembly 100 may allow for the desired engagement of the optical probe head 102 and the electrical probe head 104. The test substrate 200 (e.g., combined optical and electrical test substrate 200) may be held on a testing surface (not shown). The probe assembly 100 may be brought toward the test substrate 200. The spacer stools 128 (e.g., having been adjusted for the specific testing configuration) may contact a surface (e.g., the top surface) of the test substrate 200. Accordingly, the optical components of the optical probe head 102 may be at a desired distance from the optical components of the test substrate 200. As the probe assembly 100 is continuously moved in the direction of the test substrate 200, a displacement force may be applied to the optical probe head 102 and the optical probe head mounting platform 302 (e.g., via the spacer stools 128). Alternatively, the optical probe head mounting platform 302 (and/or the electrical probe head mounting platform) may be height adjusted (e.g., manually physically and/or electronically via actuators, software, etc.). The optical probe head mounting platform may move in relation to the mounting support structure 300. The restorative force of the springs 304 may apply a restorative force on the optical probe head mounting platform 302 and the optical probe head 102 in the direction of the test substrate 200, for example, holding the optical probe head 102 against the test substrate 200.

As the probe assembly 100 is moved in the direction of the test substrate 200, the electrical probing pins 118 may be brought into contact with the substrate electrical contacts 208. According to some example configurations, the electrical probing pins may be spring loaded to facilitate electrical connection of desired electrical probing pins 118, for example, under a range of probe approach forces and/or in order to prevent damage of the electrical probing pins 118 or test sites on the test substrate 200. Thus, if the electrical probing pins 118 are in contact (e.g., are engaged) with the substrate electrical contacts 208 for probing purposes, the optical probe head 102 may similarly be in contact with the test substrate 200 for optical probing. Additionally, disposing the optical probe head 102 in a moveable manner in relation to the mounting support structure 300 may additionally enable tilting of the optical probe head 102.

Further, it will be appreciated that the springs 304 may be adjusted to apply a desired amount of force on the surface of the test substrate 200. Thus, if the electrical probing pins 118 are in desired contact with the substrate electrical contacts 208, then the mechanics of the springs 304 may adjust the optical probe head 102 to the desired position without applying excessive force on the surface of the test substrate 200. Thereby, in addition to ensuring parallel electrical and optical probing, damage to the test substrate 200 may be avoided.

In addition or as an alternative to the springs 304, other elements may be employed to facilitate similar operations. For example, referring to FIG. 3, magnets 306 (e.g., permanent magnets, electromagnets, etc.) may be used to generate a restorative force on the optical probe head mounting platform 302 and the optical probe head 102 (e.g., similar to that which is described with respect to springs 304). In some configurations, additional benefits of electromagnets may be appreciated. For example, with electromagnets, differing restorative forces may be set and/or adjusted (e.g., dynamically) for different testing configurations and arrangements (e.g., by varying the power to the electromagnet).

Additionally, although a movable probe head assembly is only depicted (for purposes of clarity) with respect to the optical probe head 102, a substantially similar moveable probe head assembly may be additionally or alternatively employed for the electrical probe head 104. In such a configuration, the interposer 114 (e.g., referring to FIG. 2) may be replaced by, for example, wiring and appropriate harnesses. Additionally or alternatively, the optical probe head 102 and the electrical probe head 104 may be independently adjustable (e.g., independently height (e.g., distanced from the test substrate 200) adjustable). For example, the optical probe head 102 and the electrical probe head 104 may be connected to actuators to independently control height and/or offset.

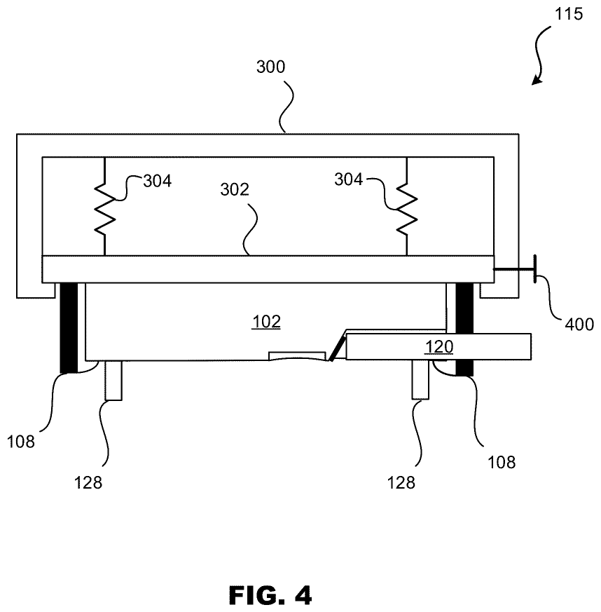

FIG. 4 depicts an alternative example of an optical probe mounting assembly 115. Referring to FIG. 4, the optical probe mounting assembly 115 may comprise axial movement adjustor 400. The axial movement adjustor 400 may allow for movement (e.g., precise movement) and retention of the optical probe head 102 (e.g., via the optical probe head mounting platform 302) in relation to the mounting support structure 300. Accordingly, the optical target on the test substrate may be addressed. Although FIG. 4 depicts an axial movement adjuster 400 on a single side (and, e.g., in a single direction), the optical probe mounting assembly 115 may comprise axial movement adjusters 400 on any or all sides of the optical probe head 102 and/or the optical probe head mounting platform 302. The axial movement adjusters 400 may be manual, motorized, piezo actuated, etc., or otherwise actuated. Additionally, although axial movement adjustor 400 and axially movable head are only depicted (for purposes of clarity) with respect to the optical probe head 102, a substantially similar moveable probe head assembly may be additionally or alternatively employed for the electrical probe head 104.

FIG. 5 depicts an alternative example probe assembly 100. Although optical probe heads 102 and electrical probe heads 104 have been described as being separate, in some example configurations, optical probing features and electrical probing features may be combined into a single, unitary optical/electrical probe head 502. Optical/electrical probe head 502 may comprise some or all of the features for optical and/or electrical probing as described with respect to optical probe heads 102, and electrical probe heads 104 (e.g., as described with reference to FIG. 1, FIG. 2, FIG. 3, and/or FIG. 4).

Additionally or alternatively, optical probe heads have been described herein for testing particular optical connection schemes. Optical probe heads described herein (e.g., optical probe head 104 of FIGS. 1, 2, 3, 4, etc.) may be configured for testing alternate optical schemes. For example, referring to FIG. 5, optical transceivers 202 on test substrate 200 may utilize (e.g., couple to, receive, transmit, etc.) a collimated optical beam 206. The optical/electrical probe head 502 may be configured to couple to the collimated optical beam 206. The optical/electrical probe head 502 may comprise optical features to couple to the collimated optical beam 206. The optical/electrical probe head 502 may comprise, for example, a beam turning element. The beam-turning element may comprise a tilted curved mirror 524 (e.g., a lensed mirror) (e.g., turning curved mirror). The tilted curved mirror 524 may be configured to interface and/or relay the optical beam between optical fiber 120 and the transceiver 202. The tilted curved mirror 524 may be further configured to transform the optical beam 206. For example, the tilted curved mirror 524 may be configured to substantially collimate the optical beam 206 (e.g., received from the optical fiber 120 source) and/or focus a substantially collimated beam toward the optical fiber 120, for example, if received from the transceiver 202.

Similarly, the transceiver 202 may be configured to utilize (e.g., couple to, receive, transmit, etc.) a focused optical beam. In a similar manner to that which is immediately previously described, the optical/electrical probe head 502 may be complementarily configured to couple to and/or utilize a focusing optical beam. For example, the tilted curved mirror 524 (and/or one or more additional or alternative optical elements) may be configured to relay and/or facilitate (e.g., turn, transform, etc.) coupling of a focusing optical beam.

Additionally or alternatively, the transceiver 202 and the substrate electrical contacts 208 can be on substantially the same plane (e.g., as depicted in FIG. 2) or offset (e.g., on different planes), for example, as depicted in FIG. 5.

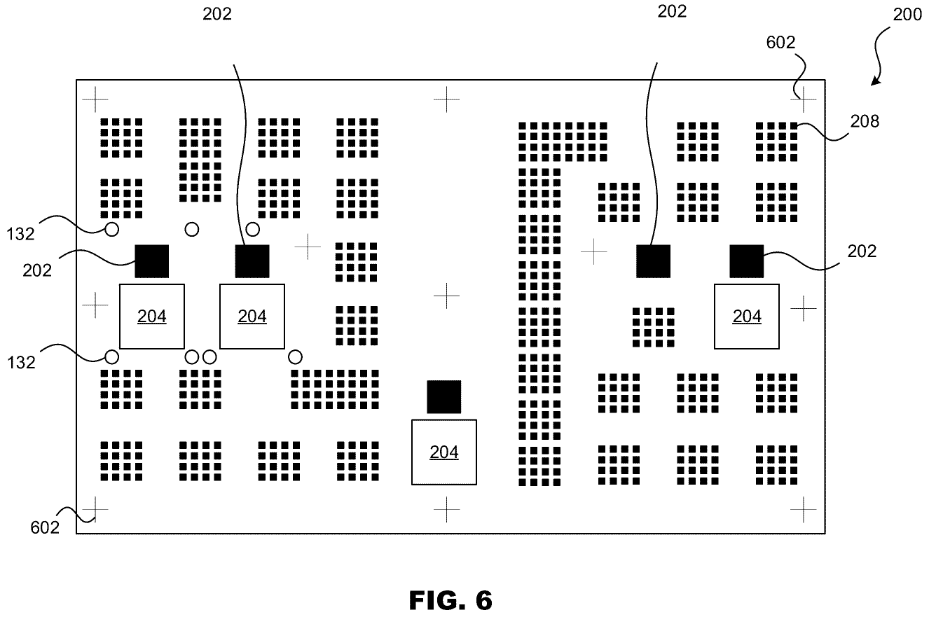

FIG. 6 depicts an example test substrate 200. Referring to FIG. 6, the test substrate 200 may comprise one or more optical transceivers 202 (although a plurality of optical transceivers 202 are depicted, for clarity, only a portion are referenced with numerals). The test substrate 200 may further comprise one or more substrate optical focusing elements 204 (e.g., curved mirror, lensed mirror, etc.). Each substrate optical focusing element 204 may correspond to a neighboring (e.g., adjacent, proximate, etc.) transceiver 202. Additionally or alternatively, one or more transceivers 202 may not correspond to an optical focusing element 204 (e.g., as described in the example configuration of FIG. 5). The optical focusing element 204 may be fabricated in or on the test substrate, for example, via wafer level manufacturing (e.g., CMOS, lithography, grayscale lithography (e.g., grayscale, imprint, etc.), etching, deposition, etc.). Additionally or alternatively, the optical focusing element 204 may be fabricated in or on a separate carrier (e.g., bump-on-carrier) (e.g., die, wafer, carrier substrate). The carrier (e.g., including the optical focusing element 204) may be added to the test substrate 200.

The test substrate may further comprise one or more substrate electrical contacts 208 (although a plurality of substrate electrical contacts 208 are depicted, for clarity, only a single substrate electrical contact 208 is referenced with numeral 208).

Transceivers 202 may be distributed on the test substrate 200. Different transceivers 202 may be of the same optical circuit or of different optical circuits. One or more optical probe heads (e.g., optical probe head 102 or optical/electrical probe head 502) may be configured to probe (e.g., test) one or more of the transceivers 202 at the same or at different times. In FIG. 6, transceivers 202 are depicted as being distributed on the test substrate 200 in one example configuration. Other example configurations may comprise more or less transceivers 202, and the transceivers 202 may be distributed differently in different example configurations.

Substrate electrical contacts 208 may be distributed on the test substrate 200. Different substrate electrical contacts 208 may be of the same electrical circuit or of different electrical circuits. One or more electrical probe heads (e.g., optical probe head 102 or optical/electrical probe head 502) may be configured to probe (e.g., test) one or more of the substrate electrical contacts 208 at the same or at different times. In FIG. 6, substrate electrical contacts 208 are depicted as being distributed on the test substrate 200 in one example configuration. Other example configurations may comprise more or less substrate electrical contacts 208, and the substrate electrical contacts 208 may be distributed differently in different example configurations.

The test substrate 200 may further comprise one or more alignment marks 602 (e.g., fiducials) (although a plurality of alignment marks 602 are depicted, for clarity, only a portion of alignment marks 602 are referenced with numeral 602). The alignment marks may be used to align the probe heads with the transceivers 202 and waver electrical contacts 208 for probing (e.g., testing). For example, the probe assembly 100 may comprise one or more sensors. The one or more sensors may be configured as imaging sensors. The one or more sensors may be configured to detect the alignment marks 602 to assist alignment of the probe heads with areas to be tested. The alignment marks 602 are depicted as intersecting lines, however, the alignment marks can be differently configured. Also or alternatively, the alignment marks 602 have been described as marks that can be detected by imaging sensors/systems. Additionally or alternatively, the alignment marks 602 may be configured to be otherwise detected. For example, the alignment marks may comprise magnetically attractive material and may be detected, for example, via hall effect sensors. Additionally or alternatively, alignment may be detected and facilitated via capacitive and/or inductive sensors. Additionally or alternatively, alignment may be detected and facilitated via interferometry.

As described herein (e.g., with reference to FIG. 2) the test substrate 200 may further comprise alignment features (e.g., fine alignment features), for example, semi-spheres 132 (FIG. 6 depicts a plurality of semi-spheres 132; for clarity, only a portion of the semi-spheres 132 are referenced with numeral 132). As described herein, semi-spheres 132 may be distributed differently for different configurations. For example, with continued reference to FIG. 6, a first transceiver 202 and substrate optical focusing element 204 may be associated with four fine alignment features (e.g., semi-spheres 132) (e.g., arranged in a substantially parallelogram pattern), and a second transceiver 202 and substrate optical focusing element 204 may be associated with three fine alignment features (e.g., semi-spheres 132) (e.g., arranged in a substantially triangle pattern). Other transceivers may be associated with different numbers and configurations of semi-spheres 132. The optical probe heads described herein (e.g., optical probe head 102, optical/electrical probe head 502) may be correspondingly configured to the test substrate 200. For example, the optical probe heads may comprise optical features corresponding to the test substrate optical features 200 and may comprise mechanical features (e.g., spacer stools 128, trenches 130, etc.) that corresponding to the test substrate 200 mechanical features (e.g., semi-spheres 132).

The mechanical features of the test substrate 200 (e.g., semi-spheres 132) may be fabricated in or on the test substrate, for example, via wafer level manufacturing (e.g., CMOS, lithography, grayscale lithography (e.g., grayscale, imprint, etc.), etching, deposition, etc.). Additionally or alternatively, the mechanical features of the test substrate 200 may be fabricated in or on a separate carrier (e.g., bump-on-carrier) (e.g., die, wafer, carrier substrate). The carrier (e.g., including the mechanical features) may be added to the test substrate 200.

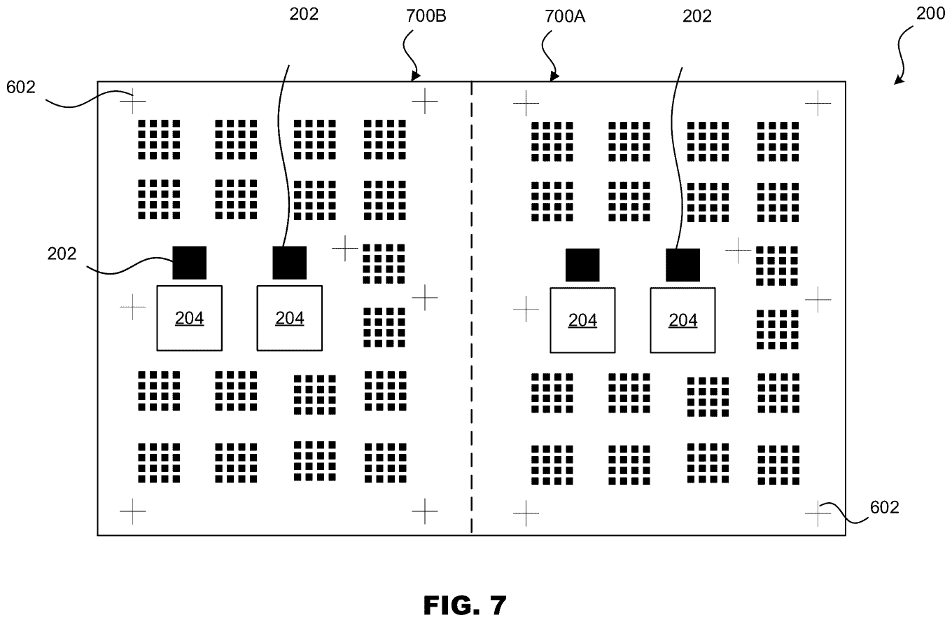

FIG. 7 depicts an example test substrate 200. For example, FIG. 7 depicts an alternative example test substrate 200. Referring to FIG. 7, the test substrate 200 may comprise a wafer having a plurality of dies 700A and 700B (generally, die 700). For example, each plurality of dies 700A and 700B may be substantially similar or different. Probe assembly 100 may be configured to probe a single die 700 or a plurality of dies 700.

Referring back to FIG. 2. The probe assembly 100 may further comprise one or more sensors 210. The sensors 210 may comprise one or more of, for example, image sensors, cameras, photodetectors, optical sensors, hall effect sensors, capacitive sensors, inductive sensors, acoustic/echo sensors, light detection ranging (LiDAR) sensors, etc. The sensors 210 may be used to align the optical probe head 102 and/or the electrical probe head 104 with the optical and/or electrical features of the test substrate 200. For example, the sensors 210 may be configured to detect one or more alignment marks (e.g., alignment marks 602 as described with reference to FIGS. 6 and 7) on the test substrate 200. Additionally or alternatively, the sensors 210 may be used to facilitated distancing of the probe heads and the test substrate 200 (e.g., via distance sensing). In configurations in which sensors are used for distancing the probe heads from the test substrate 200, spacer stools 128 may or may not be used.

Additionally or alternatively, the sensors 210 may be connected to a computing device. The sensors 210 and/or the computing device may be configured for pattern recognition. The sensors 210 and/or the computing device may scan the surface of the test substrate 200 and detect (e.g., recognize) features, for example, transceiver 202, substrate optical focusing element 204, substrate electrical contacts 208, etc. The probe assembly 100 (e.g., via a connected computing device) may be moved into desired alignment for testing based on the pattern recognition. Additionally or alternatively, the probe assembly 100, for example, via the sensors 210, may use interferometry for desired probe head alignment with the test substrate 200.

Additionally or alternatively, the optical probe head 102 and/or the electrical probe head 104 may comprise one or more alignment marks. The alignment marks on the probe head may correspond to the alignment marks 602 on the test substrate 200 (e.g., as depicted in FIG. 6 and FIG. 7). The sensor 210 may be used (e.g., in conjunction with a computing device) to align the probe side alignment marks with the test substrate 200 side alignment marks. The optical probe head 102 and/or electrical probe head 104 and the test substrate 200 may be configured such that if the probe head side alignment marks are aligned with the test substrate 200 side alignment marks 602, the probe heads may be aligned for testing.

The sensor 210 is depicted in FIG. 2 as being connected to the optical probe mounting assembly. However, it should be appreciated that the sensor 210 can be mounted anywhere on the probe assembly 100 or elsewhere.

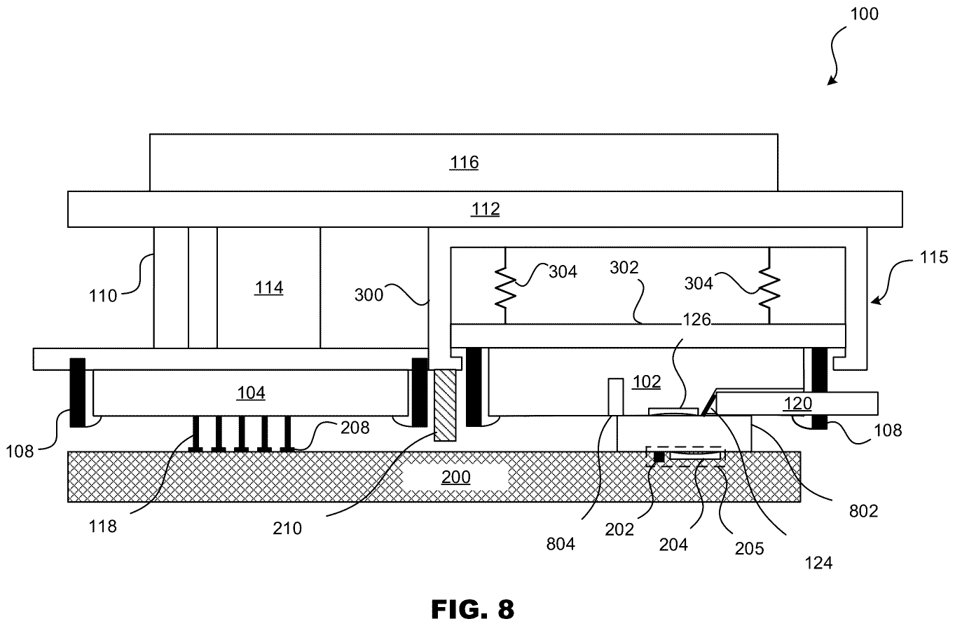

FIG. 8 depicts an example probe assembly 100. For example, FIG. 8 depicts an alternative example probe assembly 100. In use (e.g., in a computing device, e.g., in the field), the optical features of the test substrate 200 may be spaced from the optical features to which it is being connected. For example, in use, a connector may comprise one or more of the optical features described herein in relation to the optical probe head 102. A spacer layer, for example, a glass, a polymer, a resin layer, etc., may be disposed between the test substrate 200 optical elements (e.g., substrate optical focusing element 204, transceiver 202) and the connector optical elements. The spacer layer may have a particular index of refraction. The optical elements of the test substrate 200 may be configured for use with such spacer layer having a particular index of refraction. Accordingly, it may be desirable to substantially replicate such index of refraction layer when probing (e.g., testing) the optical features of the test substrate 200.

As depicted and described herein, for example, with respect to FIG. 2 and FIG. 5, the optical elements (e.g., probe head optical focusing element 126, beam turning element 124, titled curved mirror 524, etc.) of the optical probe head (e.g., optical probe head 102, optical/electrical probe head 502) may be spaced from the optical elements (e.g., transceiver 202, substrate optical focusing element 204, etc.) of the test substrate 200. The optical elements may be spaced differently based on the optical scheme used for coupling. The space may comprise an air gap. Additionally or alternatively, referring to FIG. 8, a testing spacer layer 802 may be disposed over the tested optical elements of the test substrate 200. For example, the testing spacer layer 802 may comprise, one or more of glass, resin, polymer or any material with through which light may propagate. The testing spacer layer 802 may comprise an index of refraction, for example, an index of refraction to enable the optical connection. The testing spacer layer 802 may comprise a thickness (e.g., about 50 μm or, e.g., from about 10 μm to about 100 μm, depending on configuration). The testing spacer layer 802 may be connected to the optical probe head 102 or be placed over the transceiver 202 and/or the substrate optical focusing element 204. The testing spacer layer 802 may be connected to (e.g., affixed to, attached to, etc.) the optical probe head 102 via, for example, adhesive underfill, for example between the testing spacer layer 802 and the optical probe head 102. One or more anti-reflective layers may be added (e.g., deposited), for example, at media interfaces, for example, between the testing spacer layer 802 and the optical probe head 102.

In testing environments, for example, as described herein, other methods for substantially replicating spacer layer index of refraction may be desirable. For example, it may not be desirable to place a spacer layer on each optical feature prior to testing. A fluid testing spacer layer 802 may be dispensed on the optical elements of the test substrate 200. The fluid testing spacer layer 802 may be configured to comprise an index of refraction substantially similar to the index of refraction of a spacer that will ultimately be used in the field. The probing assembly 100 may comprise a fluid dispenser 804. The fluid dispenser 804 may dispense a fluid testing spacer layer 802, for example, on the transceivers 202 and/or substrate optical focusing elements 204. The sensor 210 may be used to recognize the optical features of the tested substrate 200. Once, recognize, the probe assembly 100 may be moved (e.g., as guided by a computing device an, for example, via one or more motors) such that the fluid dispenser 804 is aligned with optical elements of the test substrate 200. The fluid dispenser 804 may deposit the fluid testing spacer layer 802 on the test substrate 200 as desired. The fluid dispenser 804 may dispense the fluid testing spacer layer 802, for example, prior to testing. Although the fluid dispenser 804 is depicted as being incorporated with and/or being comprised by the optical probe head 102, the fluid dispenser 804 may be incorporated elsewhere on the probe assembly 100 or detached from the probe assembly (e.g., as a standalone device that deposits the fluid testing spacer layer 802).

It should be understood that the optical schemes described herein with respect to optical probe head 102 may be used with the optical/electrical probe head 502, and the optical schemes described with respect to the optical/electrical probe head 502 may be used with the optical probe head 102.

FIG. 9 depicts hardware elements of a computing device 900 that may be used to implement and any other computing devices discussed herein. The computing device 900 may comprise one or more processors 901, which may execute instructions of a computer program to perform any of the functions described herein. The instructions may be stored in a non-rewritable memory 902 such as a read-only memory (ROM), a rewritable memory 903 such as random access memory (RAM) and/or flash memory, removable media 904 (e.g., a USB drive, a compact disk (CD), a digital versatile disk (DVD)), and/or in any other type of computer-readable storage medium or memory. Instructions may also be stored in an attached (or internal) hard drive 905 or other types of storage media. The computing device 900 may comprise one or more output devices, such as a display device 906 (e.g., an external or internal display device) and a speaker 914, and may comprise one or more output device controllers 907, such as a video processor or a controller for an infra-red or BLUETOOTH transceiver. One or more user input devices 908 may comprise a remote control, a keyboard, a mouse, a touch screen (which may be integrated with the display device 906), microphone, etc. The computing device 900 may also comprise one or more network interfaces, such as a network input/output (I/O) interface 910 (e.g., a network card) to communicate with an external network 909. The network I/O interface 910 may be a wired interface (e.g., electrical, RF (via coax), optical (via fiber)), a wireless interface, or a combination of the two. The network I/O interface 910 may comprise a modem configured to communicate via the external network 909. The computing device 900 may comprise a location-detecting device, such as a global positioning system (GPS) microprocessor 911, which may be configured to receive and process global positioning signals and determine, with possible assistance from an external server and antenna, a geographic position of the computing device 900. The computing device may further comprise a probe assembly I/O 916. The probe assembly I/O 916 may interface and/or communicate with one or more elements of the probe assembly 100. For example, the probe assembly I/O 916 may interface and/or communicate with one or more of the optical probe head 102, electrical probe head 104, optical/electrical probe head 502, PCB 112, interposer 114, probe station interface 116, etc.

Although FIG. 9 shows an example hardware configuration, one or more of the elements of the computing device 900 may be implemented as software or a combination of hardware and software. Modifications may be made to add, remove, combine, divide, etc. components of the computing device 900. Additionally, the elements shown in FIG. 9 may be implemented using basic computing devices and components that have been configured to perform operations such as are described herein. For example, a memory of the computing device 900 may store computer-executable instructions that, when executed by the processor 901 and/or one or more other processors of the computing device 900, cause the computing device 900 to perform one, some, or all of the operations described herein. Such memory and processor(s) may also or alternatively be implemented through one or more Integrated Circuits (ICs). An IC may be, for example, a microprocessor that accesses programming instructions or other data stored in a ROM and/or hardwired into the IC. For example, an IC may comprise an Application Specific Integrated Circuit (ASIC) having gates and/or other logic dedicated to the calculations and other operations described herein. An IC may perform some operations based on execution of programming instructions read from ROM or RAM, with other operations hardwired into gates or other logic. Further, an IC may be configured to output image data to a display buffer.

Although examples are described above, features and/or steps of those examples may be combined, divided, omitted, rearranged, revised, and/or augmented in any desired manner. Various alterations, modifications, and improvements will readily occur to those skilled in the art. Such alterations, modifications, and improvements are intended to be part of this description, though not expressly stated herein, and are intended to be within the spirit and scope of the disclosure. Accordingly, the foregoing description is by way of example only, and is not limiting.

1. A system comprising:
a probe assembly comprising:
an optical probe head comprising one or more optical elements configured to optically couple one or more optical fibers to one or more transceivers of a test substrate; and
an electrical probe head comprising one or more electrical probe elements configured to electrically test one or more electrical circuits of the test substrate.

2. The system of claim 1, wherein the probe assembly further comprises a sensor configured to detect one or more alignment marks of the test substrate to align the one or more optical elements with the one or more transceivers.

3. The system of claim 1, wherein the probe assembly further comprises a sensor configured to detect one or more features of the test substrate,
the system further comprising a computing device comprising:
one or more processors; and
memory storing instructions that, when executed by the computing device, cause the one or more processors to:
cause, based on the detected one or more features, alignment of the one or more optical elements with the one or more transceivers enabling the optical coupling of the one or more optical fibers to the one or more transceivers.

4. The system of claim 1, wherein the optical probe head is further configured to engage the one or more optical fibers.

5. The system of claim 1, wherein the optical probe head further comprises one or more first mechanical fine alignment features configured to engage one or more corresponding second fine alignment features of the test substrate.

6. The system of claim 1, wherein the probe assembly further comprises one or more magnets configured to apply a force to the optical probe head in a direction toward the test substrate.

7. A system comprising:
a first probe head configured to electrically test one or more electrical circuit of a test substrate; and
a second probe head configured to optically test one or more optical circuits of the substrate,
wherein the first probe head and the second probe head are configured to electrically test and optically test, in parallel, the substrate.

8. The system of claim 7, further comprising:
one or more optical fibers connected to the second probe head.

9. The system of claim 7, wherein the second probe head comprises one or more optical elements configured to optically couple a transceiver of the substrate to the second probe head.

10. The system of claim 9, wherein the one or more optical elements comprise a substantially flat mirror configured to turn a light beam, from a substantially horizontal orientation, toward the test substrate.

11. The system of claim 9, wherein the one or more optical elements comprise a substantially flat mirror and an optical focusing element.

12. The system of claim 7, further comprising a fluid dispenser, the fluid dispenser configured to deposit a fluid on a portion of the test substrate.

13. The system of claim 12, wherein the portion of the test substrate comprises a transceiver of the test substrate.

14. An apparatus comprising:
a probe head comprising:
optical elements comprising one or more mirrors configured to optically couple an optical fiber to a transceiver of a test substrate; and
electrical probe elements configured to electrically test one or more electrical circuits of the test substrate,
wherein the probe head is configured to optically test and electrically test, in parallel, the test substrate.

15. The apparatus of claim 14, further comprising one or more first alignment marks configured to align with one or more second alignment marks of the test substrate.

16. The apparatus of claim 14, wherein the electrical probe elements are configured to provide a voltage to the test substrate.

17. The apparatus of claim 14, wherein the electrical probe elements are spring subject to a spring force substantially in a direction toward the test substrate.

18. The probe head of claim 14, wherein the optical elements are further configured to optically test one or more optical circuits of the test substrate.

19. The apparatus of claim 14, wherein the one or more mirrors comprise a tilted substantially curved mirror configured to collimate optical beams toward the transceiver.

20. The apparatus of claim 14, wherein the probe head is further configured to engage the optical fiber.
